(19) United States
(12) Patent Application Publication
(10) Pub. No.: US 2004/0150094 A1
(43) Pub. Date: Aug. 5, 2004

(54) Stacked structure of integrated circuits

(76) Inventor: Chung Hsien Hsin, Hsinchu Hsien (TW)

Correspondence Address: PRO-TECHTOR INTERNATIONAL, 20775 Norada Court, Saratoga, CA, 95070-3018, US

(21) Appl. No.: 10/356,185

(22) Filed: Jan. 30, 2003

(51) Int. Cl. H01L 23/053

(52) U.S. Cl. 257/700

(57) ABSTRACT

A stacked structure of integrated circuits includes a substrate having signal input terminals and signal output terminals, a lower integrated circuit fixed to the substrate, an upper integrated circuit fixed to the lower integrated circuit. First wires are provided to electrically connect the lower integrated circuit to the signal input terminals of the substrate, and second wires are provided to electrically connect the upper integrated circuit to the lower integrated circuit. Signals from the upper and lower integrated circuits are gathered. The stacked structure further includes a glue layer on the substrate to cover and seal the upper and lower integrated circuits and the first and second wires.

### BACKGROUND OF THE INVENTION

1. Field of the invention

The invention relates to a stacked structure of integrated circuits, and in particular to a stacked structure of integrated circuits in which signals are gathered and integrated so as to increase the signal transmission speed and to reduce the package volume.

2. Description of the Related Art

In the current technological field, every product needs to be light, thin, and small. Therefore, it is preferable that the integrated circuit has a small volume in order to meet the demands of the products. In the prior art, even if the volumes of integrated circuits are small, they only can be electrically connected to the circuit board in parallel. Because the area of the circuit board is limited, it is not possible to increase the number of the integrated circuits mounted on the circuit board. Therefore, it is difficult to make the products small, thin, and light.

Referring to FIG. 1, a stacked structure of integrated circuits includes a substrate 10, a lower integrated circuit 12, an upper integrated circuit 14, a plurality of wires 16, and an isolation layer 18. The lower integrated circuit 12 is located on the substrate 10. The isolation layer 18 is located on the lower integrated circuit 12. The upper integrated circuit 14 is stacked on the isolation layer 18. That is, the upper integrated circuit 14 is stacked above the lower integrated circuit 12 with the isolation layer 18 interposed between the integrated circuits 12 and 14. Thus, a proper gap 20 is formed between the lower integrated circuit 12 and the upper integrated circuit 14. According to this structure, the plurality of wires 16 can be electrically connected to the edge of the lower integrated circuit 12. Furthermore, the plurality of wires 16 connecting the substrate 10 to the lower integrated circuit 12 are free from being pressed when the upper integrated circuit 14 is stacked above the lower integrated circuit 12.

However, the above-mentioned structure has the disadvantages to be described hereinbelow. During the manufacturing processes, the isolation layer 18 has to be manufactured in advance, and then, it is adhered to the lower integrated circuit 12. Thereafter, the upper integrated circuit 14 has to be adhered on the isolation layer 18. As a result, the manufacturing processes are complicated, and the manufacturing costs are high. In addition, during the wire bonding process of the plurality of wires 16, since the wires 16 have to be connected to the lower integrated circuit 12 and the upper integrated circuit 14 from the substrate 10, the wires have to be greatly curved. Therefore, the wires 16 tend to be broken and the production yield is lower.

Furthermore, the signals from the upper integrated circuit 14 are transferred to the substrate 10 and then from the substrate 10 to the lower integrated circuit 12. Then, the signals from the lower integrated circuit 12 and the upper integrated circuit 14 are gathered and integrated and then outputted to the substrate 10 as output signals. Consequently, the signal transmission distances are too long to influence the signal transmission and processing speed.

### SUMMARY OF THE INVENTION

An object of the invention is to provide a stacked structure of integrated circuits, in which the signal transmission distances may be shortened, and the signal transmission speed may be increased.

Another object of the invention is to provide a stacked structure of integrated circuits capable of integrating and gathering electrical signals to increase the efficiency of the electrical integration.

Still another object of the invention is to provide a stacked structure of integrated circuits, in which the product height may be reduced.

To achieve the above-mentioned objects, the invention provides a stacked structure of integrated circuits. The stacked structure includes:

a substrate having an upper surface on which a plurality of signal input terminals is formed, and a lower surface on which a plurality of signal output terminals is formed;

a lower integrated circuit having a first surface and a second surface, the first surface being fixed to the upper surface of the substrate, and the second surface being formed with a plurality of first bonding pads and second bonding pads;

an upper integrated circuit having a top face and a bottom face, the bottom face being fixed to the second surface of the lower integrated circuit, and the top face being formed with a plurality of third bonding pads;

a plurality of first wires for electrically connecting the first bonding pads of the lower integrated circuit to the signal input terminals of the substrate; and

a plurality of second wires for electrically connecting the third bonding pads of the upper integrated circuit to the second bonding pads of the lower integrated circuit, respectively; and

a glue layer arranged on the upper surface of the substrate to seal and cover the upper and lower integrated circuits and the first and second wires.

### BRIEF DESCRIPTION OF THE DRAWINGS

FIG. 1 is a schematic illustration showing a conventional stacked integrated circuits.

FIG. 2 is a schematic illustration showing a stacked integrated circuit of the invention.

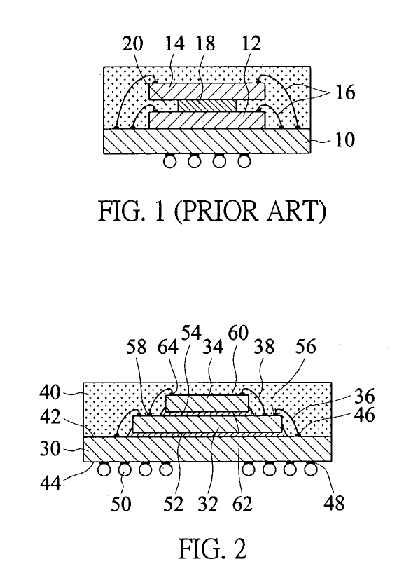

### DETAILED DESCRIPTION OF THE INVENTION

Referring to FIG. 2, a stacked structure of integrated circuits includes a substrate 30, a lower integrated circuit 32, an upper integrated circuit 34, a plurality of first wires 36, a plurality of second wires 38 and a glue layer 40.

The substrate 30 has an upper surface 42 on which a plurality of signal input terminals 46 is formed, and a lower surface 44 on which a plurality of signal output terminals 48 is formed. BGA (Ball Grid Array) metallic balls 50 are formed on the signal output terminals 48.

The lower integrated circuit 32 has a first surface 52 and a second surface 54. The first surface 52 is fixed to the upper surface 42 of the substrate 30, and a plurality of first bonding pads 56 and second bonding pads 58 are formed on the second surface 54 using a layer of mask or plural layers of masks.

The upper integrated circuit 34 has a top face 60 and a bottom face 62. The bottom face 62 is fixed to the second surface 54 of the lower integrated circuit 32, and the top face 60 is formed with a plurality of third bonding pads 64.

The first wires 36 electrically connect the first bonding pads 56 of the lower integrated circuit 32 to the signal input terminals 46 of the substrate 30.

The second wires 38 electrically connect the third bonding pads 64 of the upper integrated circuit 34 to the second bonding pads 58 of the lower integrated circuit 32, respectively, so that signals from the upper integrated circuit 34 may be transferred to the lower integrated circuit 32. In addition, signals from the upper integrated circuit 34 and the lower integrated circuit 32 are integrated and gathered, and then transferred to the substrate 30 through the first wires 36.

The glue layer 40 is arranged on the upper surface 42 of the substrate 30 to seal, cover, and protect the upper and lower integrated circuits 34, 32 and the first and second wires 36, 38.

The structure of the invention has the following advantages.

1. By transferring the signals from the upper integrated circuit 34 to the lower integrated circuit 32 and integrating and gathering the signals from the upper and lower integrated circuits 34, 32, and then transferring the signals to the substrate 30, the signal transmission distances may be shortened, the signal transmission speed may be increased, and the efficiency of the electrical integration may be improved.

2. By directly stacking the upper integrated circuit 34 above the lower integrated circuit 32, the stacked height may be effectively lowered.

3. Since the second wires 38 directly connect the upper integrated circuit 34 to the lower integrated circuit 32, the lengths of the wires are shorter, the wires do not have to be greatly curved, and it is possible to prevent the wires 38 from being broken.

While the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

What is claimed is:

1. A stacked structure of integrated circuits, comprising:
a substrate having an upper surface on which a plurality of signal input terminals is formed, and a lower surface on which a plurality of signal output terminals is formed;
a lower integrated circuit having a first surface and a second surface, the first surface being fixed to the upper surface of the substrate, and the second surface being formed with a plurality of first bonding pads and second bonding pads;
an upper integrated circuit having a top face and a bottom face, the bottom face being fixed to the second surface of the lower integrated circuit, and the top face being formed with a plurality of third bonding pads;
a plurality of first wires for electrically connecting the first bonding pads of the lower integrated circuit to the signal input terminals of the substrate; and
a plurality of second wires for electrically connecting the third bonding pads of the upper integrated circuit to the second bonding pads of the lower integrated circuit, respectively; and
a glue layer arranged on the upper surface of the substrate to seal and cover the upper and lower integrated circuits and the first and second wires.

2. The stacked structure according to claim 1, further comprising BGA (Ball Grid Array) metallic balls are formed on the signal output terminals of the substrate.

3. The stacked structure according to claim 1, wherein the first and second bonding pads are formed on the upper surface of the lower integrated circuit by using a layer of mask or plural layers of masks.
